(19) United States
(12) Patent Application Publication
(10) Pub. No.: US 2009/0151788 A1
(43) Pub. Date: Jun. 18, 2009

(54) P-TYPE DOPED LAYER OF PHOTOELECTRIC CONVERSION DEVICE AND METHOD OF FABRICATING THE SAME

(75) Inventor: Chih-Jeng Huang, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/025,772

(22) Filed: Feb. 5, 2008

(30) Foreign Application Priority Data
Dec. 13, 2007 (TW) 96147660

(51) Int. Cl. H01L 31/0256; H01L 31/04; H01L 31/18

(52) U.S. Cl. 136/261; 136/252; 438/94; 257/E31.005; 257/E31.045

(57) ABSTRACT

A P-type doped layer of a photoelectric conversion device is provided. The P-type doped layer is a double layer structure including a seeding layer and a wide band gap layer disposed thereon. The P-type doped layer with the double layer structure has both high conductivity and high photoelectric performance.

### CROSS-REFERENCE TO RELATED APPLICATION

This application claims the priority benefit of Taiwan application serial no. 96147660, filed on Dec. 13, 2007. The entirety of the above-mentioned patent application is hereby incorporated by reference herein and made a part of this specification.

### BACKGROUND OF THE INVENTION

1. Field of Invention

The present invention relates to a P-type doped layer of a photoelectric conversion device and a method of fabricating the same.

2. Description of Related Art

The supply of fossil fuels faces the shortage problem, and the combustion of fossil fuels leads to the air pollution and environmental damage. Nuclear energy can provide high electricity density, but it has the safety concern about the radiation and the storage of nuclear waste. Both of the above-mentioned energy increases the social cost. Therefore, renewable energy becomes the focus in terms of energy saving and pollution reducing. Many nations have started to develop and invest in the renewable energy and the feasibility as alternative energy.

Photovoltaic (PV) modules of photoelectric conversion devices become the mainstream of alternative energy. Solar cells (or photovoltaic cells) which can convert solar energy directly into electricity are under intensive study. Solar energy is clean and inexhaustible with few limitations. Electric power can be generated as long as sunlight exists.

The photovoltaic modules can be categorized into the following groups by the materials of solar cells: (1) single-crystalline silicon and poly-crystalline silicon solar cells; (2) thin film solar cells; (3) III-V solar cells; (4) dye-sensitizer and dye-sensitized solar cells (DSSC).

In the thin film solar cells, a photoelectric conversion layer is usually a stacked structure including a P-type doped layer, an intrinsic layer, and an N-type doped layer. The P-type doped layer serves as a window layer, and the incident sunlight enters the intrinsic layer through the P-type doped layer. Moreover, the P-type doped layer can generate the internal electric field with the N-type doped layer. Therefore, the P-type doped layer plays a very important role in solar cells.

One known P-type doped layer is formed from a hydrogenated amorphous silicon (a-Si:H) film, but the a-Si:H film have a good optical absorption of the incident sunlight. About 10-30% of the incident sunlight is lost in the P-type doped layer. It is also known that the P-type doped layer can be formed from a hydrogenated amorphous silicon carbide (a-SiC:H) film or a hydrogenated amorphous silicon oxide (a-SiO:H) film. Although the energy gap of the a-SiC:H and a-SiO:H films are high enough to help the intrinsic layer absorb the short wave sunlight, they are inclined to be an insulator rather than a conductor intrinsically; hence, the requirement of high conductivity is difficult to achieve.

### SUMMARY OF THE INVENTION

The present invention provides a P-doped layer of a photoelectric conversion device having both high conductivity and high optical energy gap so as to enhance the photoelectric performance of solar cells.

The present invention also provides a method of fabricating a P-type doped layer of a photoelectric conversion device. In accordance to the method of the present invention, the P-type doped layer can be applied to solar cells or other photoelectric devices.

A P-doped layer of a photoelectric conversion device according to the present invention is provided. The P-type doped layer includes a seeding layer and a wide band gap layer disposed thereon.

A method of fabricating a P-doped layer of a photoelectric conversion device according to the present invention is provided. First, a seeding layer is formed on a transparent conductivity substrate. The gas of forming the seeding layer may conclude silane and hydrogen, and the initial flow rate ratio of silane to hydrogen is between about 1:100 and 1:50, for example. Thereafter, a wide band gap layer is formed on the seeding layer.

In the present invention, the P-type layer is a double layer structure including a seeding layer and a wide band gap layer; it has both high conductivity and high photoelectric performance and can be applied to solar cells or other photoelectric conversion devices.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view illustrating a P-type doped layer of a photoelectric conversion device according to the first embodiment of the present invention.

FIG. 2 is a flow chart illustrating a method of fabricating a P-type doped layer of a photoelectric conversion device according to the second embodiment of the present invention.

FIG. 3 is a graph showing the relationship between the current density and the voltage according to the solar cells of the experimental group and the control group.

### DESCRIPTION OF THE PREFERRED EMBODIMENTS

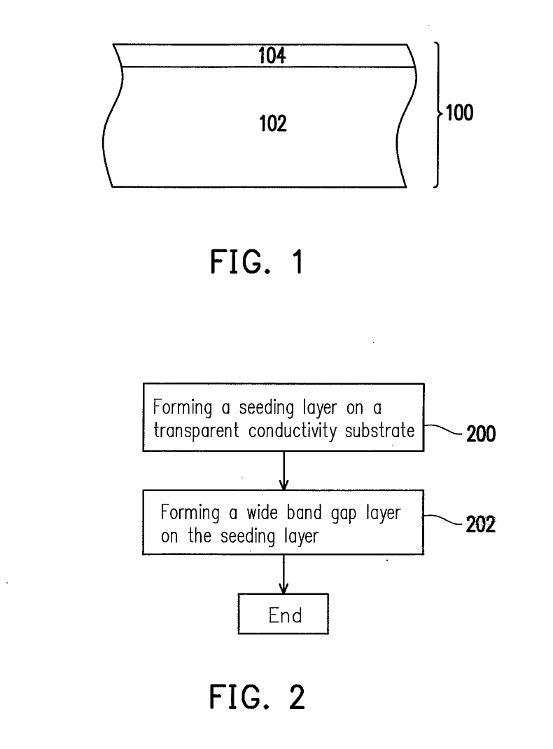

FIG. 1 is a schematic cross-sectional view illustrating a P-type doped layer of a photoelectric conversion device according to the first embodiment of the present invention.

Referring to FIG. 1, a P-type doped layer 100 includes a seeding layer 102 and a wide band gap layer 104. The wide band gap layer 104 is disposed on the seeding layer 102. The material of the seeding layer 102 is, for example, a hydrogenated nano-crystalline silicone (nc-Si:H) film, and the thickness thereof ranges from about 50 angstrom to 200 angstrom, for example. The thickness of the P-type doped layer including the seeding layer 102 and the wide band gap layer 104 ranges from about 100 angstrom to 250 angstrom, for example.

In the first embodiment, the crystallinity ratio of the seeding layer 102 is more than about 30%, and the conductivity thereof is more than about 10⁻⁶ S/cm, for example. The energy gap of the wide band gap layer 104 is more than about 1.9 eV, and the oxygen content thereof ranges from about 10¹⁸ to 10²¹ atom/cm³, for example.

FIG. 2 is a flow chart illustrating a method of fabricating a P-type doped layer of a photoelectric conversion device according to the second embodiment of the present invention.

Referring to FIG. 2, a step 200 is performed to form a seeding layer on a transparent conductive substrate. The gas of forming the seeding layer may includes silane (SiH₄) and hydrogen (H₂), and the initial flow rate ratio of silane to hydrogen is between about 1:100 and 1:50, for example. The transparent conductive substrate is formed with a transparent substrate and a transparent conductive oxide (TCO) film, for example. The material of the TCO film may include ZnO, SnO₂, indium tin oxide (ITO) or In₂O₃. The method of forming a seeding layer may include a plasma-enhanced chemical vapor deposition (PECVD) process or other suitable methods. The flow rate of hydrogen maintains the same. However, the flow rate of silane increases over time and keeps fixed after a period of time, such as 3 minutes. The period of time is determined by the crystallinity ratio of the seeding layer. For example, when the crystallinity ratio of the seeding layer is more than about 20%, i.e. the crystal starts growing, the flow rate of silane used for forming the seeding layer is fixed and not changing over time. In other words, the crystallinity ratio of the seeding layer is more than about 20% at the end of the period of time. The final flow rate ratio of silane to hydrogen is between about 1:20 and 1:5, for example.

The seeding layer formed under this experiment conditions is a nc-Si:H film, and the crystallinity ratio thereof is more than about 30% and the conductivity thereof is more than about 10⁻⁶ S/cm.

Thereafter, the step 202 is performed to form a wide band gap layer on the seeding layer. The method of forming the wide gap band layer may include a PECVD method or other suitable methods. For example, the gas of forming the wide band gap layer may include silane and hydrogen, and the flow rate ratio of island to hydrogen is between about 1:30 and 1:150, for example. The gas of forming the wide band gap layer also includes adding an oxygen source gas selected from carbon dioxide (CO₂), nitrous oxide (N₂O) or oxygen (O₂). The wide band gap layer formed under this experiment conditions is a nc-SiO:H film, and the energy gap thereof is more than about 1.9 eV and the oxygen content thereof is between about 10¹⁸ and 10²¹ atom/cm³.

How to form a highly crystallized wide band gap layer has not been reported so far. In the second embodiment, a seeding layer such as the nc-Si:H film is formed first, and the wide band gap layer such as the nc-SiO:H film grows thereon, using the seeding layer as a base crystal. Therefore, the formed P-type doped layer has high crystallinity and high conductivity.

An experimental group and a control group are provided below to prove the performance of the present invention.

### [Experimental Group]

First, a transparent conductivity substrate is provided. In accordance with the method of the present invention, a nc-Si:H film is formed on the transparent conductivity substrate as a seeding layer, and the thickness thereof ranges from about 50 angstrom to 200 angstrom. Thereafter, a nc-SiO:H film is formed on the nc-Si:H film as a wide band gap layer. The formed P-type doped layer with the double layer structure has the thickness of about 100 angstrom to 250 angstrom. Then, an intrinsic layer, an N-type doped layer and a conductive layer are formed on the P-type doped layer so as to form the solar cell.

### [Control Group]

An a-SiC:H film is formed as a P-type doped layer by the known method, and the thickness thereof is about 200 angstrom. Other layers are formed with the same methods of the experimental group.

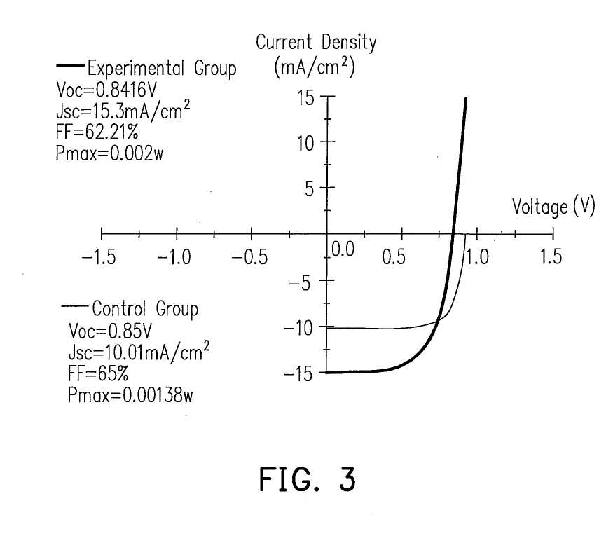

FIG. 3 is a graph showing the relationship between the current density and the voltage according to the solar cells of the experimental group and the control group. In FIG. 3, Voc stands for open circuit current, Jsc stands for short circuit current, Pmax stands for maximum output power, and FF stands for fill factor, all of which can indicate the performance of solar cells. In FIG. 3, the photoelectric efficiency of the solar cell of the experimental group is about 8%, and that of the control group is about 5.525%. Therefore, the P-type doped layer according to the present invention can enhance the photoelectric efficiency of the solar cell.

In summary, the seeding layer of the P-type doped layer in accordance of the present invention has the better photoelectric performance than the known a-Si:H film, such as high doped efficiency, high conductivity and low light absorption. The wide band gap layer on the seeding layer can help the intrinsic layer absorb the short wave sunlight due to the high energy gap. Therefore, the P-type doped layer provided by the present invention has the combined advantages of the seeding layer and the wide band gap layer; it not only has high conductivity but also has good photoelectric performance. In addition, the P-type doped layer can lower the energy barrier between the transparent conductivity substrate and the P-type doped layer and thus the current of the solar cell is increased.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A P-type doped layer of a photoelectric conversion device, comprising:
a seeding layer; and
a wide band gap layer disposed on the seeding layer.

2. The P-type doped layer of the photoelectric conversion device according to claim 1, wherein a material of the seeding layer comprises a hydrogenated nano-crystalline silicon (nc-Si:H) film.

3. The P-type doped layer of the photoelectric conversion device according to claim 1, wherein a material of the wide band gap layer comprises a hydrogenated nano-crystalline silicon oxide (nc-SiO:H) film.

4. The P-type doped layer of the photoelectric conversion device according to claim 1, wherein a thickness of the seeding layer is greater than or equal to a thickness of the wide band gap layer.

5. The P-type doped layer of the photoelectric conversion device according to claim 1, wherein a crystallinity ratio of the seeding layer is more than 30%.

6. The P-type doped layer of the photoelectric conversion device according to claim 1, wherein a conductivity of the seeding layer is more than 10⁻⁶ S/cm.

7. The P-type doped layer of the photoelectric conversion device according to claim 1, wherein an energy gap of the wide band gap layer is more than 1.9 eV.

8. The P-type doped layer of the photoelectric conversion device according to claim 1, wherein an oxygen content of the wide band gap layer ranges from 10¹⁸ to 10²¹ atom/cm³.

9. A method of fabricating a P-type doped layer of a photoelectric conversion device, comprising:
forming a seeding layer on a transparent conductivity substrate, wherein a gas of forming the seeding layer comprises silane and hydrogen, and an initial flow rate ratio of silane to hydrogen is between 1:100 and 1:50; and
forming a wide band gap layer on the seeding layer.

10. The method according to claim 9, wherein a flow rate of silane used for forming the seeding layer increases over time in a period of time and keeps fixed after the period of time.

11. The method according to claim 10, wherein a crystallinity ratio of the seeding layer is more than 20% at an end of the period of time.

12. The method according to claim 9, a flow rate of hydrogen used for forming the seeding layer keeps the same.

13. The method according to claim 9, wherein a final flow rate ratio of silane to hydrogen used for forming the seeding layer is between 1:20 and 1:5.

14. The method according to claim 9, wherein a gas of forming the wide band gap layer comprises silane and hydrogen, and a flow rate ratio of silane to hydrogen is between 1:30 and 1:150.

15. The method according to claim 9, wherein a gas of forming the wide band gap layer further comprises carbon dioxide (CO₂), nitrous oxide (N₂O) or oxygen (O₂).
